(19) United States
(12) Patent Application Publication
(10) Pub. No.: US 2009/0256222 A1
(43) Pub. Date: Oct. 15, 2009

(54) Packaging method of image sensing device

(75) Inventor: Chih-Yang Hsu, Tao-Yuan Hsien (TW)

Correspondence Address: BACON & THOMAS, PLLC, 625 SLATERS LANE, FOURTH FLOOR, ALEXANDRIA, VA, 22314-1176, US

(73) Assignee: Impac Technology Co., Ltd., Tao-Yuan Hsien (TW)

(21) Appl. No.: 12/081,268

(22) Filed: Apr. 14, 2008

(51) Int. Cl. H01L 21/00; H01L 31/00

(52) U.S. Cl. 257/432; 438/64; 257/E21.001; 257/E31.001

(57) ABSTRACT

A packaging method for an image sensing device is disclosed. The packaging method includes the steps of a) providing an annular dam on a substrate; b) mounting an image sensing module, having a light-receiving region exposed, inside the annular dam on the substrate; c) connecting the image sensing module and the substrate via a plurality of bonding wires; d) forming a barrier around the light-receiving region on the image sensing module; e) filling an adhesive between the barrier and the annular dam with the plurality of bonding wires being encapsulated; f) forming a transparent lid above the light-receiving region; and g) cutting off the annular dam.

### FIELD OF THE INVENTION

The present invention relates to a semiconductor packaging method, and more particularly, to a packaging method of an image sensing device.

### BACKGROUND OF THE INVENTION

In recent years, solid-state image sensors such as charge coupled devices (CCDs) or complementary metal oxide semiconductor (CMOS) image sensors have been widely applied to electronic products for converting light into electrical signals. The applications of image sensor components include monitors, cell phones, transcription machines, scanners, digital cameras, and so on.

Conventionally, these sensors have been packaged for use by mounting them to a substrate and enclosing them within a housing assembly. For example, U.S. Pat. No. 6,268,231 discloses a CCD package having a plastic base structure, a flexible plastic circuit board mounted on the base structure, a plastic rim mounted on the circuit board, a CCD sensor mounted on the circuit board and inside the rim, and a glass cover mounted on the rim. The CCD sensor is wire bonded to the circuit board. The plastic base structure, circuit board and rim, not to mention the glass cover, make for a relatively thick package. U.S. Pat. Nos. 6,034,429, 6,268,654 and 6,143,588 also disclose a CCD package including an IC die mounted on and wire bonded to a first side of a BT substrate, a bead or dam formed in varying manners around the IC die, a glass lid attached to the bead, and solder balls attached to a second side of the BT substrate. All of these packages are relatively thick and large in size due to the use of a rim, bead, or dam to support a glass lid.

To overcome the aforementioned drawbacks of traditional image sensing packaging method, U.S. Pat. No. 7,195,940 discloses in one embodiment, an image sensor package which is assembled by surrounding a chip with a barrier of transfer mold compound and covering the chip with a transparent lid. In another embodiment of the invention, the perimeter area of a chip, including interconnections such as wire bonds and bond pads, is encapsulated with a liquid dispensed epoxy, and a transparent lid is attached. In yet another embodiment of the invention, chip encapsulation is accomplished with a unitary shell of entirely transparent material. In yet another embodiment of the invention, a substrate-mounted chip and a transparent lid are loaded into a transfer mold that holds them in optimal alignment. The transfer mold is then filled with molding compound to encapsulate the chip and interconnections, and to retain the transparent lid. Although the size of the image sensor package is reduced, the production cost of the molding is quite high.

Therefore, a packing method of an image sensing device with minimized size and low production cost is desired.

### SUMMARY OF THE INVENTION

Accordingly, the prior arts are limited by the above problems. It is an object of the present invention to provide a packaging method that can produce an image sensing device having bonding wires encapsulated without using molding so that the production cost can be reduced.

In accordance with an aspect of the present invention, a packaging method for an image sensing device, includes the steps of a) providing an annular dam on a substrate; b) mounting an image sensing module, having a light-receiving region exposed, inside the annular dam on the substrate; c) connecting the image sensing module and the substrate via a plurality of bonding wires; d) forming a barrier around the light-receiving region on the image sensing module; e) filling an adhesive between the barrier and the annular dam with the plurality of bonding wires being encapsulated; f) forming a transparent lid above the light-receiving region; and g) cutting off the annular dam.

Preferably, the image sensing module includes complementary metal oxide semiconductor (CMOS) image sensor or charge coupled device (CCD) image sensor.

Preferably, the substrate includes aluminum nitride ceramic, fiberglass-reinforced epoxy resin, or bismaleimide-triazine resin.

Preferably, the barrier is formed by transfer molding, pot molding, injection molding, photolithographic process, exposure development process, laser cutting process, or stereolithographic process.

Preferably, the barrier is defined using a photoresist mask.

Preferably, the barrier is made of epoxy, solder mask, or photoresist.

Preferably, the step e) further includes the steps of e1) forming a protecting layer on the light-receiving region of the image sensing module; e2) flattening the barrier, the protecting layer, the annular dam, and the adhesive; and e3) removing the protecting layer to expose the light-receiving region of the image sensing module.

Preferably, the protecting layer is formed by transfer molding, pot molding, injection molding, photolithographic process, exposure development process, laser cutting process, or stereolithographic process.

Preferably, the protecting layer is defined using a photoresist mask.

Preferably, the protecting layer is made of epoxy, solder mask, or photoresist.

In accordance with another aspect of the present invention, an image sensing device includes a substrate; an image sensing module mounted on the substrate, having a light-receiving region exposed; a plurality of bonding wires for connecting the image sensing module and the substrate; a barrier formed around the light-receiving region on the image sensing module; an adhesive filled around the barrier with the plurality of bonding wires being encapsulated; and a transparent lid formed above the light-receiving region.

### BRIEF DESCRIPTION OF THE DRAWING

The above objects and advantages of the present invention will become more readily apparent to those ordinarily skilled in the art after reviewing the following detailed description and accompanying drawings, in which:

FIGS. 1-10 illustrate an embodiment of packaging method for an image sensing device according to the present invention.

### DETAILED DESCRIPTION OF THE PREFERRED EMBODIMENT

The present invention will now be described more specifically with reference to the following embodiment. It is to be noted that the following descriptions of preferred embodiment of this invention are presented herein for purpose of illustration and description only; it is not intended to be exhaustive or to be limited to the precise form disclosed.

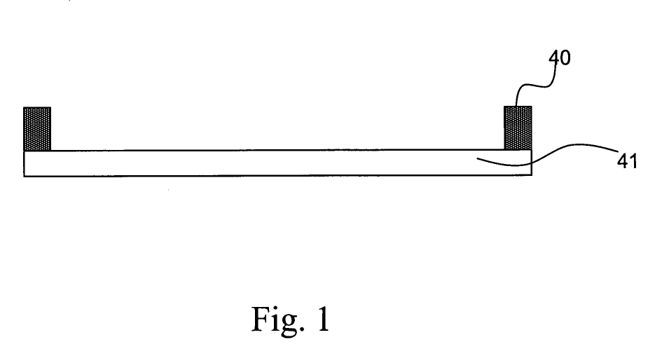

Please refer to FIGS. 1-10. They illustrate an embodiment of packaging method for an image sensing device according to the present invention. Firstly, please refer to FIG. 1. There is an annular dam 40 on a substrate 41 which could be made by plastic, fiberglass-reinforced epoxy resin, or bismaleimide-triazine resin. Furthermore, the substrate 41 could also be made of aluminum nitride ceramic for improving the thermal conductivity.

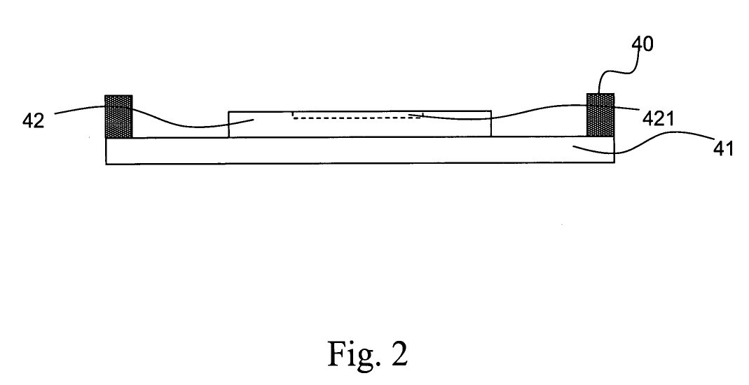

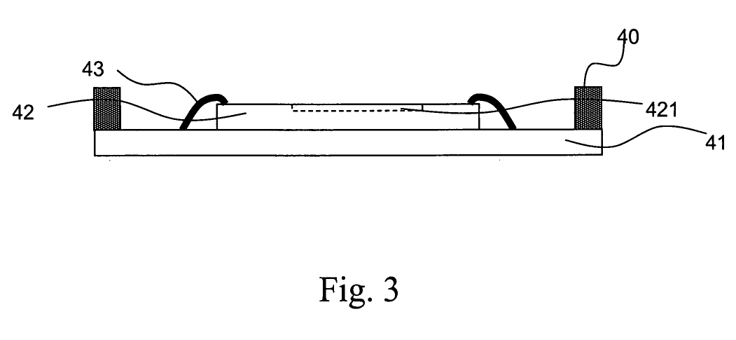

As shown in FIG. 2, an image sensing module 42, having a light-receiving region 421 exposed, is mounted on the substrate 41. The image sensing module 42 is mounted on the substrate 41 in a conventional manner such as tape lamination process. Usually, there are a lot of connecting pads (not shown) disposed on the image sensing module 42 and the substrate 41. Accordingly, those connecting pads of the image sensing module 42 and the substrate 41 are conducted via a plurality of bonding wires 43, as shown in FIG. 3.

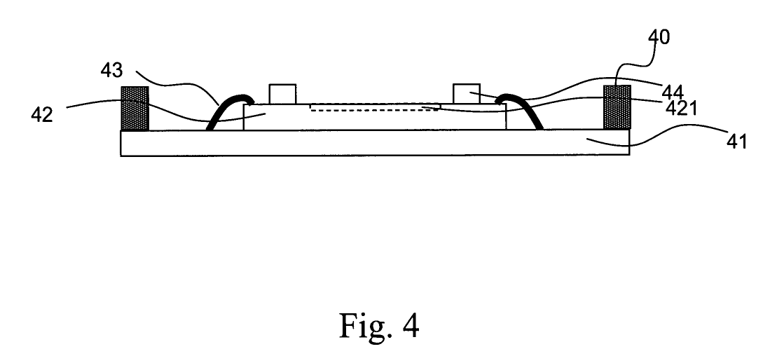

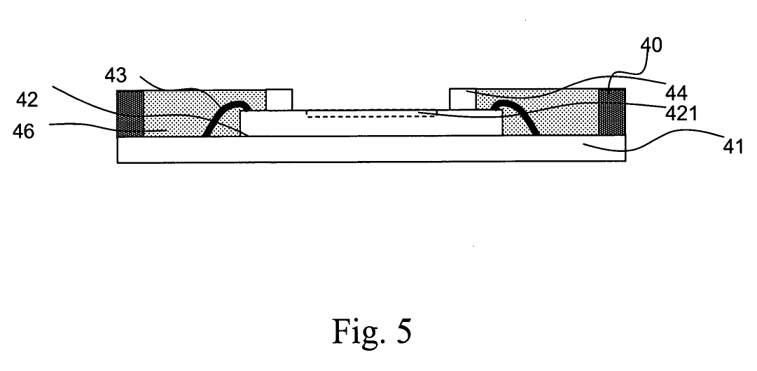

After that, a barrier 44 is formed on the image sensing module 42, as shown in FIG. 4. The barrier 44 is disposed around the light-receiving region 421 of the image sensing module 42. An adhesive 46 is filled between the barrier 44 and the annular dam 40 with the bonding wires 43 being encapsulated, as shown in FIG. 5.

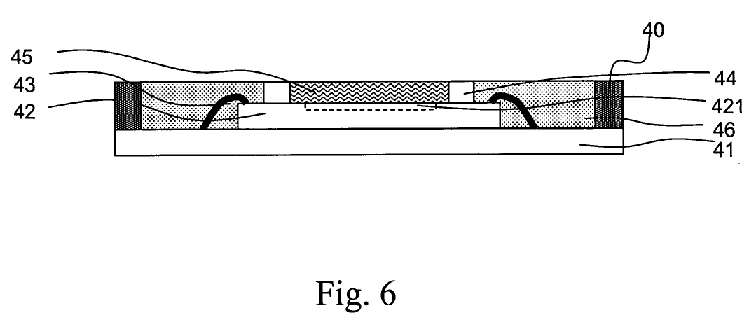

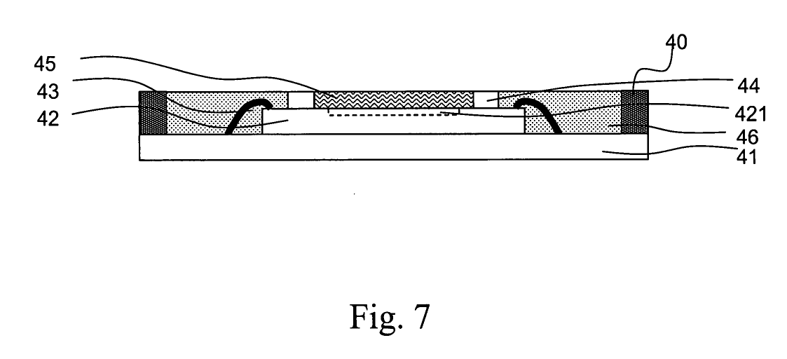

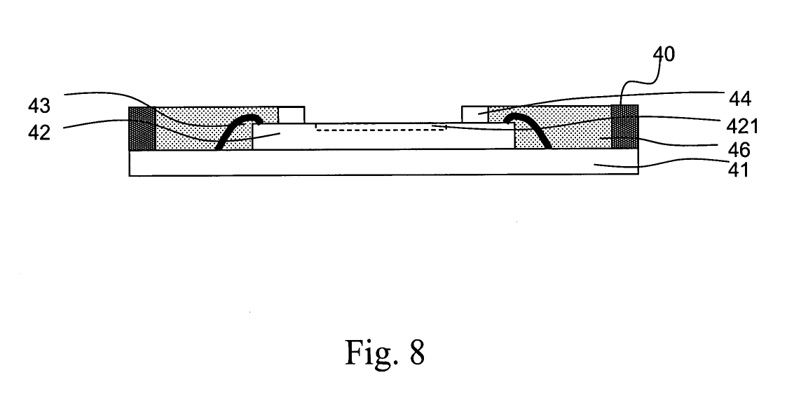

Moreover, a protecting layer 45 is further formed over the light-receiving region 421 of the image sensing module 42 for protecting the light-receiving region 421 of the image sensing module 42 during the following flattening process, as shown in FIG. 6. After the adhesive 46 is added between the barrier 44 and the annular dam 40, the entire surface of the barrier 44, the protecting layer 45, the adhesive 46, and the annular dam 40 might not be flat or smooth, and therefore, a flattening process is preferred to obtain an entire flatten surface, as shown in FIG. 7. After flattening, a uniform flatness across the barrier 44, the protecting layer 45, the adhesive 46, and the annular dam 40 can be produced. Accordingly, the protecting layer 45 can be removed to expose the light-receiving region 421 of the image sensing module 42, as shown in FIG. 8.

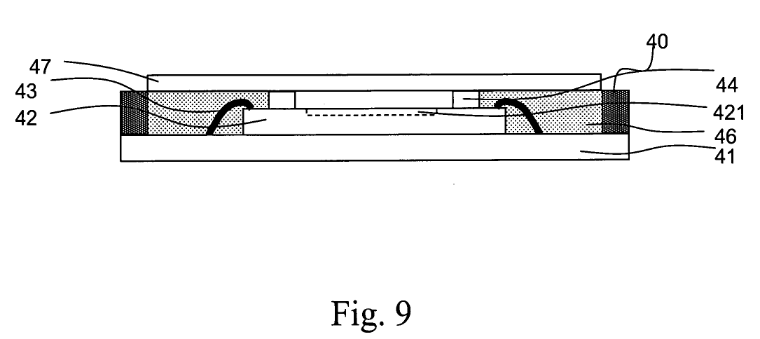

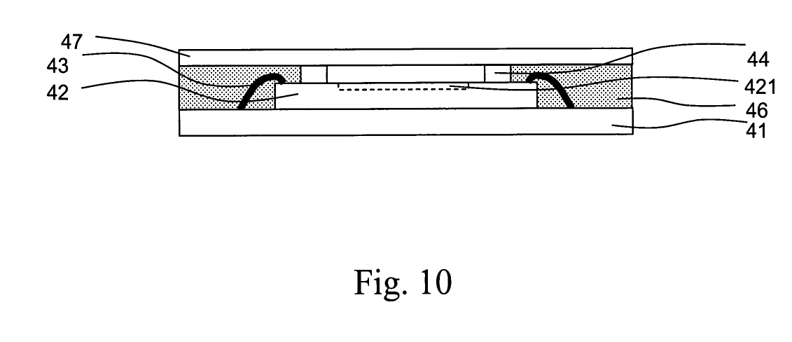

Later, a transparent lid 47 is disposed on the flatten surface in parallel with the surface of the light-receiving region 421 of the image sensing module 42 so as to avoid light refraction while light passes through the transparent lid 47 of the image sensing module 42, as shown in FIG. 9. Finally, the annular dam 40 and a part of the substrate 41 are cut off to reduce the size of the image sensing device, as shown in FIG. 10.

In practice, the image sensing module 42 of the present invention could be complementary metal oxide semiconductor (CMOS) image sensor or charge coupled device (CCD) image sensor. In this embodiment, the barrier 44 can be formed by transfer molding, pot molding, injection molding, photolithographic process, exposure development process, laser cutting process, or stereolithographic process. Due to the fact that the barrier 44 has a certain volume and height, the barrier 44 is usually defined using a photoresist mask.

In conclusion, the present invention discloses a packaging method that can produce an image sensing device having bonding wires encapsulated without using molding so that the production cost can be reduced.

While the invention has been described in terms of what is presently considered to be the most practical and preferred embodiment, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A packaging method for an image sensing device, comprising the steps of:
a) providing an annular dam on a substrate;
b) mounting an image sensing module, having a light-receiving region exposed, inside said annular dam on said substrate;
c) connecting said image sensing module and said substrate via a plurality of bonding wires;
d) forming a barrier around said light-receiving region on said image sensing module;
e) filling an adhesive between said barrier and said annular dam with said plurality of bonding wires being encapsulated;
f) forming a transparent lid above said light-receiving region; and
g) cutting off said annular dam.

2. The packaging method according to claim 1, wherein said image sensing module comprises complementary metal oxide semiconductor (CMOS) image sensor or charge coupled device (CCD) image sensor.

3. The packaging method according to claim 1, wherein said substrate comprises aluminum nitride ceramic, fiberglass-reinforced epoxy resin, or bismaleimide-triazine resin.

4. The packaging method according to claim 1, wherein said barrier is formed by transfer molding, pot molding, injection molding, photolithographic process, exposure development process, laser cutting process, or stereolithographic process.

5. The packaging method according to claim 1, wherein said barrier is defined using a photoresist mask.

6. The packaging method according to claim 1, wherein said barrier is made of epoxy, solder mask, or photoresist.

7. The packaging method according to claim 1, wherein said step e) further comprises the steps of:
e1) forming a protecting layer on said light-receiving region of said image sensing module;
e2) flattening said barrier, said protecting layer, said annular dam, and said adhesive; and
e3) removing said protecting layer to expose said light-receiving region of said image sensing module.

8. The packaging method according to claim 7, wherein said protecting layer is formed by transfer molding, pot molding, injection molding, photolithographic process, exposure development process, laser cutting process, or stereolithographic process.

9. The packaging method according to claim 7, wherein said protecting layer is defined using a photoresist mask.

10. The packaging method according to claim 7, wherein said protecting layer is made of epoxy, solder mask, or photoresist.

11. An image sensing device, comprising:
a substrate;
an image sensing module mounted on said substrate, having a light-receiving region exposed;
a plurality of bonding wires for connecting said image sensing module and said substrate;
a barrier formed around said light-receiving region on said image sensing module;
an adhesive filled around said barrier with said plurality of bonding wires being encapsulated; and
a transparent lid formed above said light-receiving region.

12. The image sensing device according to claim 11, wherein said image sensing module comprises complementary metal oxide semiconductor (CMOS) image sensor or charge coupled device (CCD) image sensor.

13. The image sensing device according to claim 11, wherein said substrate comprises aluminum nitride ceramic, fiberglass-reinforced epoxy resin, or bismaleimide-triazine resin.

14. The image sensing device according to claim 11, wherein said barrier is formed by transfer molding, pot molding, injection molding, photolithographic process, exposure development process, laser cutting process, or stereolithographic process.

15. The image sensing device according to claim 11, wherein said barrier is defined using a photoresist mask.

16. The image sensing device according to claim 11, wherein said barrier is made of epoxy, solder mask, or photoresist.
